(19) United States
(12) Patent Application Publication
(10) Pub. No.: US 2012/0032249 A1
(43) Pub. Date: Feb. 9, 2012

(54) NONVOLATILE SEMICONDUCTOR MEMORY DEVICE AND METHOD FOR MANUFACTURING NONVOLATILE SEMICONDUCTOR MEMORY DEVICE

(75) Inventor: Toru MATSUDA, Mie-ken (JP)

(73) Assignee: KABUSHIKI KAISHA TOSHIBA, Tokyo (JP)

(21) Appl. No.: 12/955,214

(22) Filed: Nov. 29, 2010

(30) Foreign Application Priority Data
Aug. 5, 2010 (JP) 2010-176667

(51) Int. Cl. H01L 29/792; H01L 21/336

(52) U.S. Cl. 257/324; 438/479; 257/E29.309; 257/E21.423

(57) ABSTRACT

According to one embodiment, a nonvolatile semiconductor memory device includes a multilayer body, a semiconductor pillar, a memory layer, a first insulating film and a second insulating film. The multilayer body includes a plurality of interelectrode insulating films and a plurality of electrode films alternately stacked in a first direction. The semiconductor pillar penetrates through the multilayer body in the first direction. The memory layer is provided between each of the electrode films and the semiconductor pillar and extends in the first direction. The first insulating film is provided between the memory layer and the semiconductor pillar and extends in the first direction. The second insulating film is provided between each of the electrode films and the memory layer and extends in the first direction. The second insulating film is projected between the electrode films.

### CROSS-REFERENCE TO RELATED APPLICATIONS

This application is based upon and claims the benefit of priority from the prior Japanese Patent Application No. 2010-176667, filed on Aug. 5, 2010; the entire contents of which are incorporated herein by reference.

### FIELD

Embodiments described herein relate generally to a nonvolatile semiconductor memory device and a method for manufacturing the nonvolatile semiconductor memory device.

### BACKGROUND

Collectively processed three-dimensional multilayer memory cells have been proposed to increase the memory capacity of a nonvolatile semiconductor memory device.

A nonvolatile semiconductor memory device including such memory cells is manufactured by alternately stacking sacrificial films and electrode films (constituting word lines) to form a multilayer body, and collectively forming through holes or trenches in this multilayer body. The sacrificial film is removed through the through hole or trench, and an insulating film is formed in the space formed by the removal.

However, when the sacrificial film is removed, the portion supporting the electrode film is small, and the position of the electrode film may vary. By the variation in the position of the electrode film, the electrode films may be brought into contact with each other. This may decrease the yield.

### BRIEF DESCRIPTION OF THE DRAWINGS

FIG. 1 is a schematic perspective view illustrating a nonvolatile semiconductor memory device according to a first embodiment;

FIG. 2 is a schematic sectional view of portion A in FIG. 1;

FIG. 3 is a schematic perspective view illustrating a nonvolatile semiconductor memory device according to a second embodiment;

FIGS. 4A to 7B are schematic process sectional views illustrating a method for manufacturing a nonvolatile semiconductor memory device according to a third embodiment;

FIG. 8 is a schematic process sectional view illustrating a method for manufacturing a nonvolatile semiconductor memory device according to a comparative example;

FIGS. 9A to 12B are schematic process sectional views illustrating a method for manufacturing a nonvolatile semiconductor memory device according to a fourth embodiment;

FIG. 13 is a schematic process sectional view illustrating a method for manufacturing a nonvolatile semiconductor memory device according to a comparative example; and

FIGS. 14A to 17B are schematic process sectional views illustrating a method for manufacturing a nonvolatile semiconductor memory device according to a fifth embodiment.

### DETAILED DESCRIPTION

In general, according to one embodiment, a nonvolatile semiconductor memory device includes a multilayer body, a semiconductor pillar, a memory layer, a first insulating film and a second insulating film. The multilayer body includes a plurality of interelectrode insulating films and a plurality of electrode films alternately stacked in a first direction. The semiconductor pillar penetrates through the multilayer body in the first direction. The memory layer is provided between each of the electrode films and the semiconductor pillar and extends in the first direction. The first insulating film is provided between the memory layer and the semiconductor pillar and extends in the first direction. The second insulating film is provided between each of the electrode films and the memory layer and extends in the first direction. The second insulating film is projected between the electrode films.

In general, according to another embodiment, a method for manufacturing a nonvolatile semiconductor memory device is disclosed. The method can include forming a multilayer body by alternately stacking a plurality of sacrificial films and a plurality of electrode films in a first direction. The method can include forming a through hole penetrating through the multilayer body in the first direction. The method can include removing a portion of the sacrificial films facing the through hole by a prescribed dimension and filling the through hole with a first sacrificial member. The method can include forming a first trench penetrating through the multilayer body in the first direction. The method can include removing the sacrificial films through the first trench, forming an interelectrode insulating film through the first trench and removing the first sacrificial member. In addition, the method can include forming a second insulating film, a memory layer, and a first insulating film in this order on an inner surface of the through hole, and burying silicon inside the first insulating film.

In general, according to another embodiment, a method for manufacturing a nonvolatile semiconductor memory device is disclosed. The method can include forming a multilayer body by alternately stacking a plurality of sacrificial films and a plurality of electrode films in a first direction. The method can include forming a first trench penetrating through the multilayer body in the first direction. The method can include removing a portion of the sacrificial films facing the first trench by a prescribed dimension and filling the first trench with a third insulating film. The method can include forming a through hole penetrating through the multilayer body in the first direction. The method can include removing the sacrificial films through the through hole. In addition, the method can include forming a second insulating film, a memory layer, and a first insulating film in this order on an inner surface of the through hole, and burying silicon inside the first insulating film.

Embodiments will now be illustrated with reference to the drawings.

In the figures, similar components are labeled with like reference numerals, and the detailed description thereof is omitted as appropriate. The arrows X, Y, Z in the figures represent mutually orthogonal three directions. For instance, the direction perpendicular to the major surface 11a of the semiconductor substrate 11 is defined as Z-axis direction (first direction). One direction in the plane parallel to the major surface 11a is defined as Y-axis direction (second direction). The direction perpendicular to the Z axis and the Y axis is defined as X-axis direction.

In this specification, with regard to a plurality of semiconductor pillars, when all or any of the semiconductor pillars are referred to, the term “semiconductor pillar SP” is used. When a particular semiconductor pillar is referred to in illustrating, for instance, the relationship between semiconductor pillars, the term “n-th semiconductor pillar SPn” (n is any integer of one or more) is used.

In this specification, “perpendicular” and “parallel” mean not only being exactly perpendicular and exactly parallel, but include, for instance, variations in the manufacturing process, and only need to mean substantially perpendicular and substantially parallel.

First, a nonvolatile semiconductor memory device according to the embodiments is illustrated.

### First Embodiment

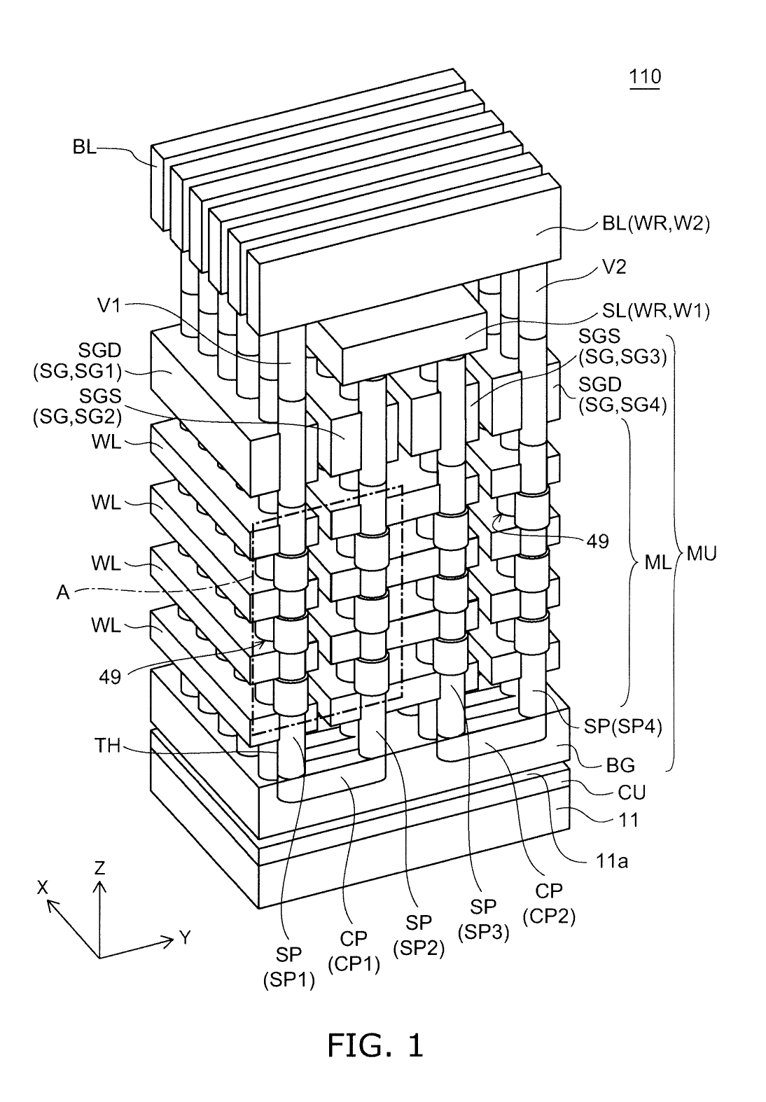

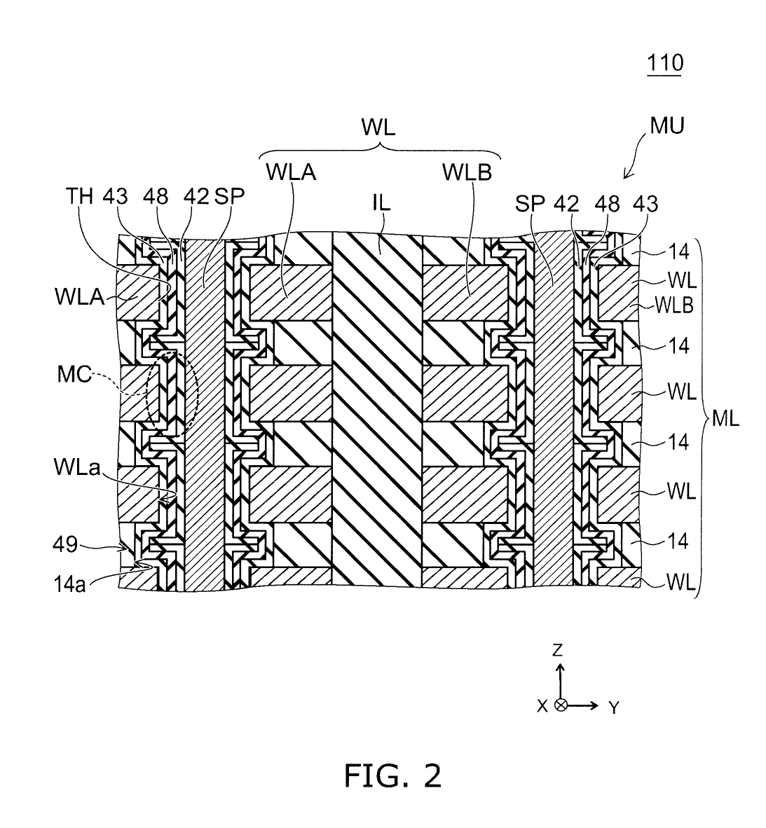

FIG. 1 is a schematic perspective view illustrating a nonvolatile semiconductor memory device according to a first embodiment. FIG. 2 is a schematic sectional view of portion A in FIG. 1.

In FIG. 1, for clarity of illustration, only the conductive portions are shown, and illustration of the insulating portions is omitted.

The nonvolatile semiconductor memory device 110 illustrated in FIGS. 1 and 2 is a collectively processed three-dimensional multilayer flash memory.

First, the general configuration of the nonvolatile semiconductor memory device 110 is illustrated.

As shown in FIGS. 1 and 2, the nonvolatile semiconductor memory device 110 includes a memory unit MU. The memory unit MU is provided on the major surface 11a of a semiconductor substrate 11 illustratively made of single crystal silicon.

The semiconductor substrate 11 can include a circuit unit CU, and the memory unit MU can be provided above the circuit unit CU. In the case of providing a circuit unit CU, an interlayer insulating film, not shown, illustratively made of silicon oxide is provided between the circuit unit CU and the memory unit MU. Here, the circuit unit CU is not necessarily needed, but can be provided as necessary.

The memory unit MU includes a multilayer body ML, a semiconductor pillar SP penetrating through the multilayer body ML in the Z-axis direction, a memory layer 48, an inner insulating film 42 (first insulating film), an outer insulating film 43 (second insulating film), and a wiring WR.

The multilayer body ML includes a plurality of interelectrode insulating films 14 and a plurality of electrode films WL alternately stacked in the Z-axis direction. The electrode films WL and the interelectrode insulating films 14 are provided parallel to the major surface 11a. The electrode film WL is divided for each erase block. For instance, as shown in FIG. 2, the electrode film WL is divided by an insulating layer IL into a first region (electrode film WLA) and a second region (electrode film WLB).

The memory layer 48 is provided between each electrode film WL and the semiconductor pillar SR The memory layer 48 extends in the Z-axis direction. The inner insulating film 42 is provided between the memory layer 48 and the semiconductor pillar SP. The inner insulating film 42 extends in the Z-axis direction. The outer insulating film 43 is provided between each electrode film WL and the memory layer 48. The outer insulating film 43 extends in the Z-axis direction. The wiring WR is electrically connected to one end of the semiconductor pillar SP.

That is, on the wall surface inside the through hole TH penetrating through the multilayer body ML in the Z-axis direction, the outer insulating film 43, the memory layer 48, and the inner insulating film 42 are formed in this order. The remaining space thereof is filled with a semiconductor to form a semiconductor pillar SP.

Furthermore, between the electrode films WL, a protrusion 49 is provided as a projection of at least the outer insulating film 43 projected radially outside the semiconductor pillar SP.

Here, the projecting amount of the protrusion 49 can illustratively be 10 nm or more.

Thus, the end portion 14a of the interelectrode insulating film 14 facing the semiconductor pillar SP is provided at a position farther from the semiconductor pillar SP than the end portion WLa of the electrode film WL facing the semiconductor pillar SP.

As illustrated in FIG. 2, the protrusion 49 can also be a projection in which the outer insulating film 43, the memory layer 48, and the inner insulating film 42 are projected. Alternatively, the protrusion 49 can also be a projection in which the outer insulating film 43 and the memory layer 48 are projected, or a projection in which the outer insulating film 43 is projected.

That is, at least the outer insulating film 43 is projected between the electrode films WL.

By the projection of at least the outer insulating film 43 between the electrode films WL, the position in the Z-axis direction of the electrode film WL is retained.

A memory cell MC is provided at the intersection of the electrode film WL and the semiconductor pillar SP. That is, at the intersections of the electrode films WL and the semiconductor pillars SP, memory cell transistors including the memory layers 48 are provided in a three-dimensional matrix. By accumulating electric charge in this memory layer 48, each memory cell transistor functions as a memory cell MC for storing data.

The inner insulating film 42 functions as a tunnel insulating film in the memory cell transistor of the memory cell MC. The outer insulating film 43 functions as a block insulating film in the memory cell transistor of the memory cell MC. The interelectrode insulating film 14 functions as an interlayer insulating film for insulating the electrode films WL from each other.

The electrode film WL can be made of any conductive material, such as amorphous silicon or polysilicon endowed with conductivity by impurity doping. Alternatively, metals and alloys can also be used therefor. The electrode film WL is applied with a prescribed electrical signal and functions as a word line of the nonvolatile semiconductor memory device 110.

The interelectrode insulating film 14, the inner insulating film 42, and the outer insulating film 43 can illustratively be silicon oxide films. The interelectrode insulating film 14, the inner insulating film 42, and the outer insulating film 43 may be either single layer films or multilayer films.

The memory layer 48 can illustratively be a silicon nitride film. The memory layer 48 accumulates or releases electric charge by the electric field applied between the semiconductor pillar SP and the electrode film WL and functions as a portion for storing information. The memory layer 48 may be either a single layer film or a multilayer film.

As described later, the interelectrode insulating film 14, the inner insulating film 42, the memory layer 48, and the outer insulating film 43 are not limited to the materials illustrated above, but can be made of any material.

Here, FIGS. 1 and 2 illustrate the case where the multilayer body ML includes four electrode films WL. However, the number of electrode films WL provided in the multilayer body ML is arbitrary. In the following, as an example, the case where four electrode films WL are provided is illustrated.

As shown in FIG. 1, two semiconductor pillars SP are connected by a connecting portion CP. That is, the connecting portion CP is provided below the multilayer body ML and connects the lower end portions of an adjacent pair of semiconductor pillars SP to each other. The two semiconductor pillars SP and the connecting portion CP form a U-shaped semiconductor pillar, which constitutes a U-shaped NAND string.

The memory unit MU includes a first semiconductor pillar SP1, a second semiconductor pillar SP2, and a first connecting portion CP1 (connecting portion CP). Furthermore, the memory unit MU includes a third semiconductor pillar SP3, a fourth semiconductor pillar SP4, and a second connecting portion CP2.

The first semiconductor pillar SP1 penetrates through the multilayer body ML in the Z-axis direction. The second semiconductor pillar SP2 is adjacent to the first semiconductor pillar SP1 in the Y-axis direction and penetrates through the multilayer body ML in the Z-axis direction. The first connecting portion CP1 extends in the Y-axis direction. The first connecting portion CP1 electrically connects the first semiconductor pillar SP1 and the second semiconductor pillar SP2 on the same side (the semiconductor substrate 11 side) in the Z-axis direction. The material of the first connecting portion CP1 can be the same as that of the first semiconductor pillar SP1 and the second semiconductor pillar SP2.

The third semiconductor pillar SP3 is adjacent to the second semiconductor pillar SP2 on the opposite side of the second semiconductor pillar SP2 from the first semiconductor pillar SP1 in the Y-axis direction and penetrates through the multilayer body ML in the Z-axis direction. The fourth semiconductor pillar SP4 is adjacent to the third semiconductor pillar SP3 on the opposite side of the third semiconductor pillar SP3 from the second semiconductor pillar SP2 in the Y-axis direction and penetrates through the multilayer body ML in the Z-axis direction. The second connecting portion CP2 extends in the Y-axis direction. The material of the second connecting portion CP2 can be the same as that of the third semiconductor pillar SP3 and the fourth semiconductor pillar SP4.

Above the major surface 11a of the semiconductor substrate 11, a back gate BG (connecting portion conductive layer) is provided via an interlayer insulating film. A trench is provided in the portion of the back gate BG opposed to the semiconductor pillars. Inside the trench, an outer insulating film 43, a memory layer 48, and an inner insulating film 42 are formed. The remaining space thereof is filled with a connecting portion CP made of a semiconductor. Here, the formation of the outer insulating film 43, the memory layer 48, the inner insulating film 42, and the connecting portion CP in the trench is performed simultaneously and collectively with the formation of the outer insulating film 43, the memory layer 48, the inner insulating film 42, and the semiconductor pillar SP in the through hole TH.

The end portion of the first semiconductor pillar SP1 on the opposite side from the first connecting portion CP1 is connected to a bit line BL (second wiring W2). The end portion of the second semiconductor pillar SP2 on the opposite side from the first connecting portion CP1 is connected to a source line SL (first wiring W1).

The bit lines BL are provided in a plurality above the multilayer body ML and extend in the Y-axis direction orthogonal to the Z-axis direction.

The source lines SL are provided in a plurality above the multilayer body ML and extend in another direction being orthogonal to the Z-axis direction and crossing the Y-axis direction.

The end portion of the fourth semiconductor pillar SP4 on the opposite side from the second connecting portion CP2 is connected to a bit line BL (second wiring W2). The end portion of the third semiconductor pillar SP3 on the opposite side from the second connecting portion CP2 is connected to a source line SL (first wiring W1).

The first semiconductor pillar SP1 is connected to the bit line BL by a via V1. The fourth semiconductor pillar SP4 is connected to the bit line BL by a via V2. The wiring WR includes the first wiring W1 and the second wiring W2.

In the example illustrated in FIG. 1, the bit line BL extends in the Y-axis direction, and the source line SL extends in the X-axis direction.

Between the multilayer body ML and the bit line BL, a drain side select gate electrode SGD (first select gate electrode SG1, or select gate electrode SG) is provided opposite to the first semiconductor pillar SP1, and a source side select gate electrode SGS (second select gate electrode SG2, or select gate electrode SG) is provided opposite to the second semiconductor pillar SP2.

A source side select gate electrode SGS (third select gate electrode SG3, or select gate electrode SG) is provided opposite to the third semiconductor pillar SP3, and a drain side select gate electrode SGD (fourth select gate electrode SG4, or select gate electrode SG) is provided opposite to the fourth semiconductor pillar SP4.

Thus, desired data can be written to and read from any memory cell MC in any semiconductor pillar SP.

The select gate electrode SG can be made of any conductive material. For instance, the material of the select gate electrode SG can be polysilicon or amorphous silicon. In the example illustrated in FIG. 1, the select gate electrode SG is divided in the Y-axis direction and shaped like a strip extending along the X-axis direction.

Here, an interlayer insulating film is provided between the select gate electrode SG and the multilayer body ML. An interlayer insulating film is provided also between the select gate electrodes SG.

A through hole is provided in the select gate electrode SG. A select gate insulating film of a select gate transistor is provided on the inner side surface of the through hole. A semiconductor is buried inside the select gate insulating film. This semiconductor is connected to the semiconductor pillar SP.

That is, the memory unit MU includes a select gate electrode SG stacked on the multilayer body ML in the Z-axis direction. The select gate electrode SG is penetrated by the semiconductor pillar SP on the side of the wiring WR (at least one of the source line SL and the bit line BL).

An interlayer insulating film is provided around the source line SL and the vias 22 (vias V1, V2). An interlayer insulating film is provided also between the bit lines BL. The bit line BL is shaped like a strip along the Y-axis direction.

The material of the interlayer insulating film and the select gate insulating film described above can illustratively be silicon oxide.

Next, the operation of the nonvolatile semiconductor memory device 110 according to this embodiment is illustrated. To write data to a memory cell MC, the potential of a pair of select gate electrodes SG located on both sides of that memory cell MC is made higher than the potential of the semiconductor pillar SP serving as a channel. Then, the potential of that memory cell MC increases by the coupling effect, and electrons are injected from the semiconductor pillar SP into the memory layer 48 by the tunneling effect. The injected electrons are accumulated in the memory layer 48. Thus, data is written to that memory cell MC.

To erase data written in the memory cell MC, the potential of the semiconductor pillar SP is made higher than the potential of the memory cell MC. Hence, electrons accumulated in the memory cell MC are extracted into the semiconductor pillar SP by the tunneling effect, or holes are injected therein. Thus, the data is erased.

To read data written in the memory cell MC, the threshold of the memory transistor is detected to determine whether electrons are accumulated in the memory layer 48.

In the nonvolatile semiconductor memory device 110 according to this embodiment, at least the outer insulating film 43 is projected between the electrode films WL. Furthermore, the end portion 14a of the interelectrode insulating film 14 facing the semiconductor pillar SP is provided at a position farther from the semiconductor pillar SP than the end portion WLa of the electrode film WL facing the semiconductor pillar SP. Thus, when the sacrificial film is removed in the manufacturing process, the portion supporting the electrode film WL can be increased. Hence, variation in the position of the electrode film WL can be suppressed. Consequently, contact between the electrode films WL can be suppressed, and hence the yield can be increased. Here, the details of increasing the portion supporting the electrode film WL when removing the sacrificial film are described later.

### Second Embodiment

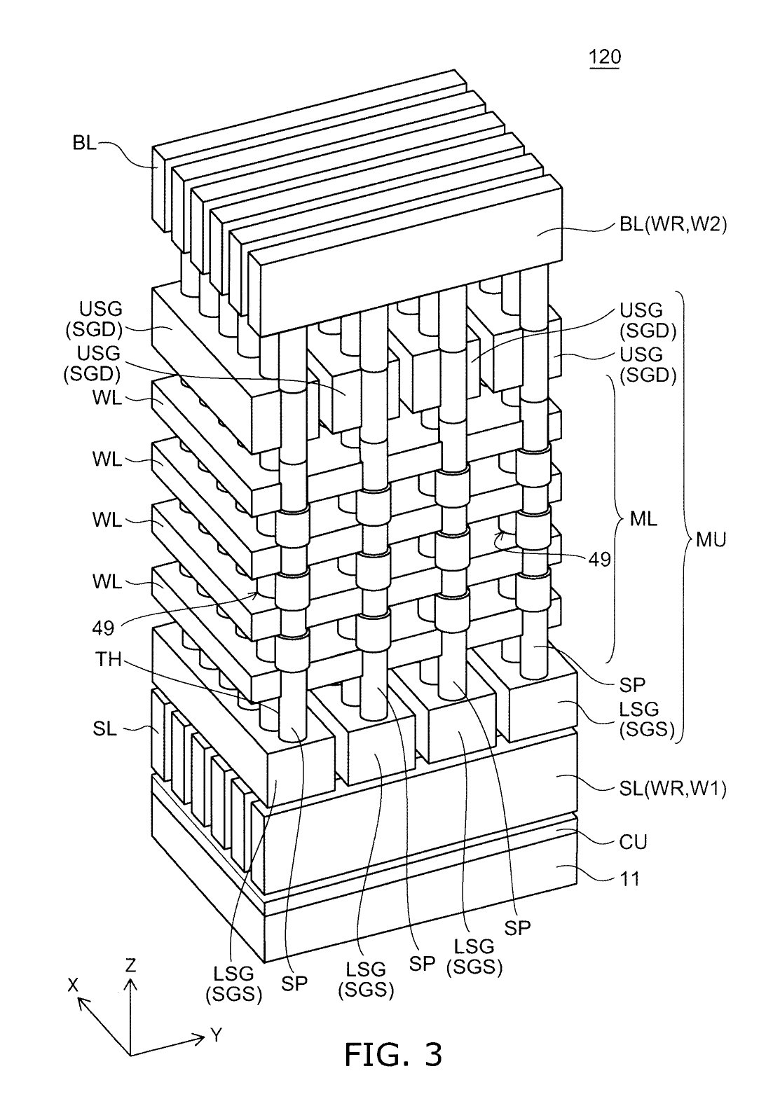

FIG. 3 is a schematic perspective view illustrating a nonvolatile semiconductor memory device according to a second embodiment. In FIG. 3, for clarity of illustration, only the conductive portions are shown, and illustration of the insulating portions is omitted.

As shown in FIG. 3, the nonvolatile semiconductor memory device 120 according to this embodiment also includes a memory unit MU.

However, in this embodiment, the semiconductor pillars SP are not connected into a U-shape, but each semiconductor pillar SP is independent. That is, the nonvolatile semiconductor memory device 120 includes a linear NAND string. Furthermore, an upper select gate electrode USG (e.g., serving as a drain side select gate electrode SGD) is provided above the multilayer body ML, and a lower select gate electrode LSG (e.g., serving as a source side select gate electrode SGS) is provided below the multilayer body ML.

An upper select gate insulating film illustratively made of silicon oxide is provided between the upper select gate electrode USG and the semiconductor pillar SP. A lower select gate insulating film illustratively made of silicon oxide is provided between the lower select gate electrode LSG and the semiconductor pillar SP.

Furthermore, a source line SL (wiring WR, e.g., first wiring W1) is provided below the lower select gate electrode LSG. An interlayer insulating film is provided below the source line SL. An interlayer insulating film is provided also between the source line SL and the lower select gate electrode LSG.

Below the lower select gate electrode LSG, the semiconductor pillar SP is connected to the source line SL. Above the upper select gate electrode USG, the semiconductor pillar SP is connected to the bit line BL (wiring WR, e.g., second wiring W2). Thus, memory cells MC are formed in the multilayer body ML between the upper select gate electrode USG and the lower select gate electrode LSG. The semiconductor pillar SP functions as one linear NAND string.

The upper select gate electrode USG and the lower select gate electrode LSG are each divided in the Y-axis direction by the interlayer insulating film and shaped like a strip extending along the X-axis direction.

On the other hand, the bit line BL connected to the upper portion of the semiconductor pillar SP, and the source line SL connected to the lower portion of the semiconductor pillar SP, are shaped like strips extending in the Y-axis direction. That is, the bit lines BL are provided in a plurality above the multilayer body ML and extend in the Y-axis direction. The source lines SL are provided in a plurality below the multilayer body ML and extend in the Y-axis direction.

In the example illustrated in FIG. 3, the electrode film WL is a plate-like conductive film parallel to the X-Y plane.

Also in this embodiment, like the example illustrated in FIG. 2, between the electrode films WL, a protrusion 49 is provided as a projection of at least the outer insulating film 43 projected radially outside the semiconductor pillar SP. Here, the projecting amount of the protrusion 49 can illustratively be 10 nm or more.

Thus, the end portion 14a of the interelectrode insulating film 14 facing the semiconductor pillar SP is provided at a position farther from the semiconductor pillar SP than the end portion WLa of the electrode film WL facing the semiconductor pillar SP.

Here, the protrusion 49 can also be a projection in which the outer insulating film 43, the memory layer 48, and the inner insulating film 42 are projected. Alternatively, the protrusion 49 can also be a projection in which the outer insulating film 43 and the memory layer 48 are projected, or a projection in which the outer insulating film 43 is projected. That is, at least the outer insulating film 43 is projected between the electrode films WL.

Also in the nonvolatile semiconductor memory device 120 according to this embodiment, at least the outer insulating film 43 is projected between the electrode films WL. Furthermore, the end portion 14a of the interelectrode insulating film 14 facing the semiconductor pillar SP is provided at a position farther from the semiconductor pillar SP than the end portion WLa of the electrode film WL facing the semiconductor pillar SP. Thus, when the sacrificial film is removed in the manufacturing process, the portion supporting the electrode film WL can be increased. Hence, variation in the position of the electrode film WL can be suppressed. Consequently, contact between the electrode films WL can be suppressed, and hence the yield can be increased.

In the nonvolatile semiconductor memory device 110 and 120 illustrated above, the interelectrode insulating film 14, the inner insulating film 42, and the outer insulating film 43 can be a single layer film made of a material selected from the group consisting of silicon oxide, silicon nitride, silicon oxynitride, aluminum oxide, aluminum oxynitride, hafnia, hafnium aluminate, hafnia nitride, hafnium nitride aluminate, hafnium silicate, hafnium nitride silicate, lanthanum oxide, and lanthanum aluminate, or a multilayer film made of a plurality of materials selected from the group.

Furthermore, the memory layer 48 can be a single layer film made of a material selected from the group consisting of silicon nitride, silicon oxynitride, aluminum oxide, aluminum oxynitride, hafnia, hafnium aluminate, hafnia nitride, hafnium nitride aluminate, hafnium silicate, hafnium nitride silicate, lanthanum oxide, and lanthanum aluminate, or a multilayer film made of a plurality of materials selected from the group.

Next, a method for manufacturing a nonvolatile semiconductor memory device according to the embodiments is illustrated.

### Third Embodiment

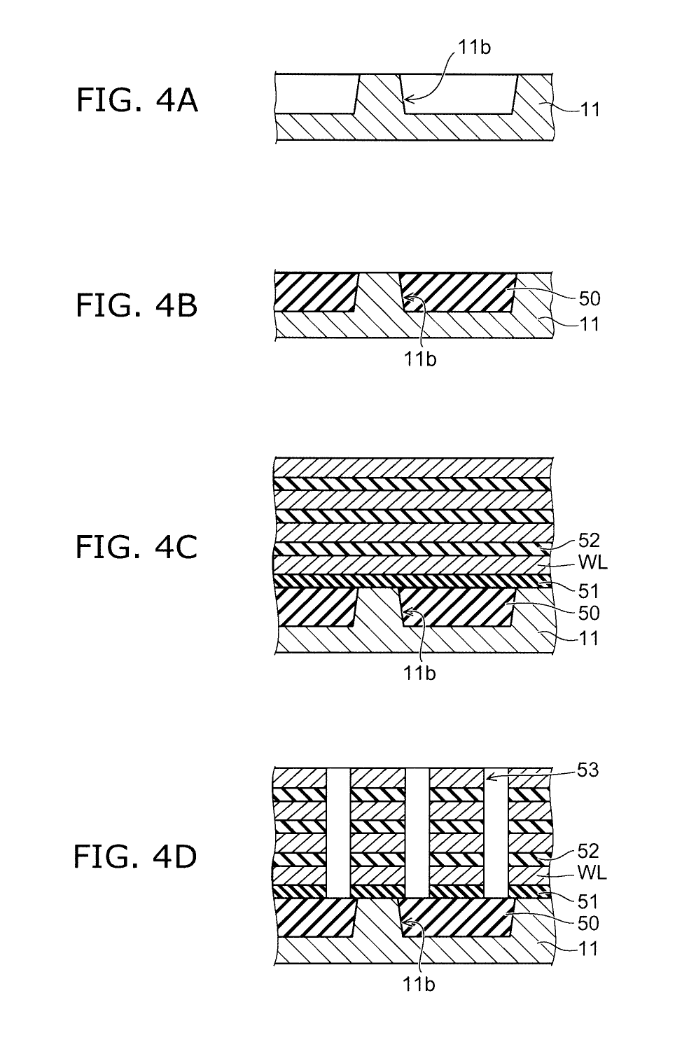

FIGS. 4A to 7B are schematic process sectional views illustrating a method for manufacturing a nonvolatile semiconductor memory device according to a third embodiment.

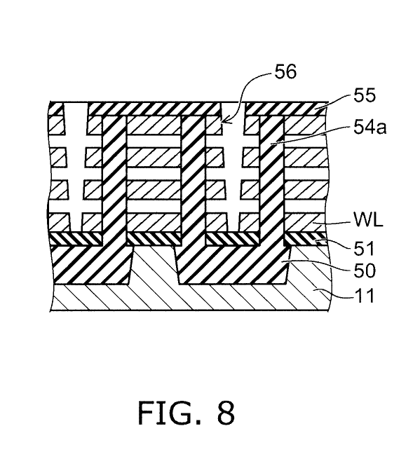

FIG. 8 is a schematic process sectional view illustrating a method for manufacturing a nonvolatile semiconductor memory device according to a comparative example.

First, transistors (transistors in a peripheral circuit unit), not shown, for controlling memory cells MC are formed in a semiconductor substrate 11.

Then, a polysilicon film is formed so as to cover the transistors. Then, as shown in FIG. 4A, a trench 11b (second trench) is formed in the surface of the formed polysilicon film by photolithography.

Next, as shown in FIG. 4B, a sacrificial member 50 (second sacrificial member) illustratively made of silicon nitride is buried in the trench 11b. Then, by overall etching, etch back is performed until the semiconductor substrate 11 is exposed.

Next, as shown in FIG. 4C, an insulating film 51 made of e.g. silicon oxide is formed to a thickness capable of maintaining insulation between the semiconductor substrate 11 and the lowermost electrode film WL. Then, electrode films WL and sacrificial films 52 are alternately stacked on the insulating film 51 to form a multilayer body. That is, a multilayer body is formed above the semiconductor substrate 11 with the sacrificial member 50 buried therein.

Here, the electrode film WL is formed from e.g. boron-doped polysilicon to a thickness such that the electrode film WL can function as a gate electrode.

The sacrificial film 52 can be formed from e.g. non-doped polysilicon.

While the case of stacking four electrode films WL is illustrated as an example, the number of stacked layers can be modified as appropriate.

Next, as shown in FIG. 4D, etching is performed from above the multilayer body to form through holes 53 reaching both end portions of the sacrificial member 50.

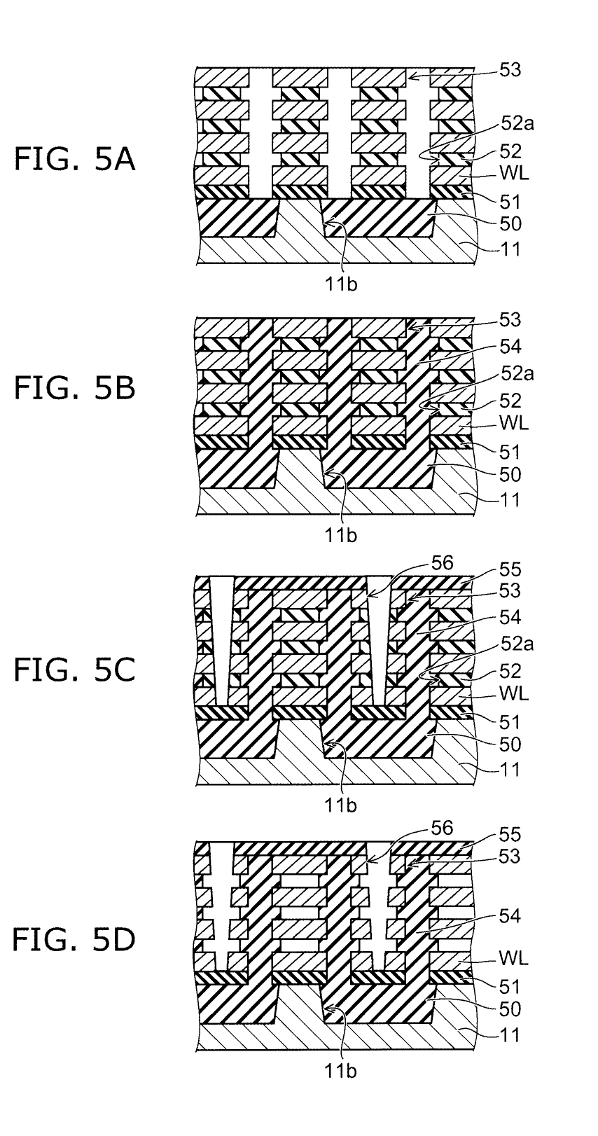

Next, as shown in FIG. 5A, the sacrificial film 52 is removed by a prescribed amount using dry etching or wet etching.

That is, the portion 52a of the sacrificial film 52 facing the through hole 53 is removed by a prescribed dimension through the through hole 53. For instance, the sacrificial film 52 can be removed by 10 nm or more from the inner surface of the through hole 53. However, the removed amount is set so as not to reach the trench 56 (first trench) to be formed later.

Examples of the dry etching can include reactive ion etching (RIE). Examples of the wet etching can include a process using chemicals such as dilute hydrofluoric acid. However, the etching process is not limited thereto, but a process capable of selectively removing the sacrificial film 52 can be selected as appropriate.

Next, as shown in FIG. 5B, the through hole 53 is filled with a sacrificial member 54 (first sacrificial member) made of silicon nitride. Then, by overall etching, etch back is performed until the uppermost electrode film WL is exposed.

At this time, the portion 52a of the sacrificial film 52 facing the through hole 53 has been removed by a prescribed dimension. Hence, part of the side surface of the sacrificial member 54 is inserted between the electrode films WL. That is, in the step of filling the through hole 53 with the sacrificial member 54, the space formed by removing the sacrificial film 52 is also filled with the sacrificial member 54.

Next, as shown in FIG. 5C, a protective film 55 made of e.g. silicon oxide is formed. Then, etching is performed from above the multilayer body to form a trench 56 penetrating through the multilayer body in the Z-axis direction to the insulating film 51.

The thickness of the protective film 55 can be set to a thickness capable of protecting the uppermost electrode film WL in forming the trench 56. The electrode films WL are divided by the trench 56 so that the lower end of the trench 56 is located above around the center of the sacrificial member 50.

Next, as shown in FIG. 5D, the sacrificial film 52 is removed by e.g. wet etching. The removal of the sacrificial film 52 can be performed through the trench 56. Examples of the wet etching can include an alkaline chemical treatment.

Here, when the sacrificial film 52 is removed, the position of the electrode film WL may vary due to stress by chemicals and surface tension of chemicals.

For instance, in the case where a columnar sacrificial member 54a is formed as in the comparable example shown in FIG. 8, when the sacrificial film 52 is removed, the portion supporting the electrode film WL is only the side surface of the sacrificial member 54a. Hence, the force supporting the electrode film WL is weak. Thus, the position of the electrode film WL may vary due to stress by chemicals and surface tension of chemicals. Then, by the variation in the position of the electrode film WL, the electrode films WL may be brought into contact with each other. This may decrease the yield.

In contrast, according to this embodiment, as illustrated in FIG. 5A, the portion 52a of the sacrificial film 52 facing the through hole 53 is removed by a prescribed dimension. Hence, part of the side surface of the sacrificial member 54 can be inserted between the electrode films WL.

Thus, the electrode film WL can be supported in the manner of sandwiching the electrode film WL by the portion inserted between the electrode films WL. This can suppress the variation in the position of the electrode film WL due to stress by chemicals and surface tension of chemicals. Consequently, contact between the electrode films WL can be suppressed, and hence the yield can be increased.

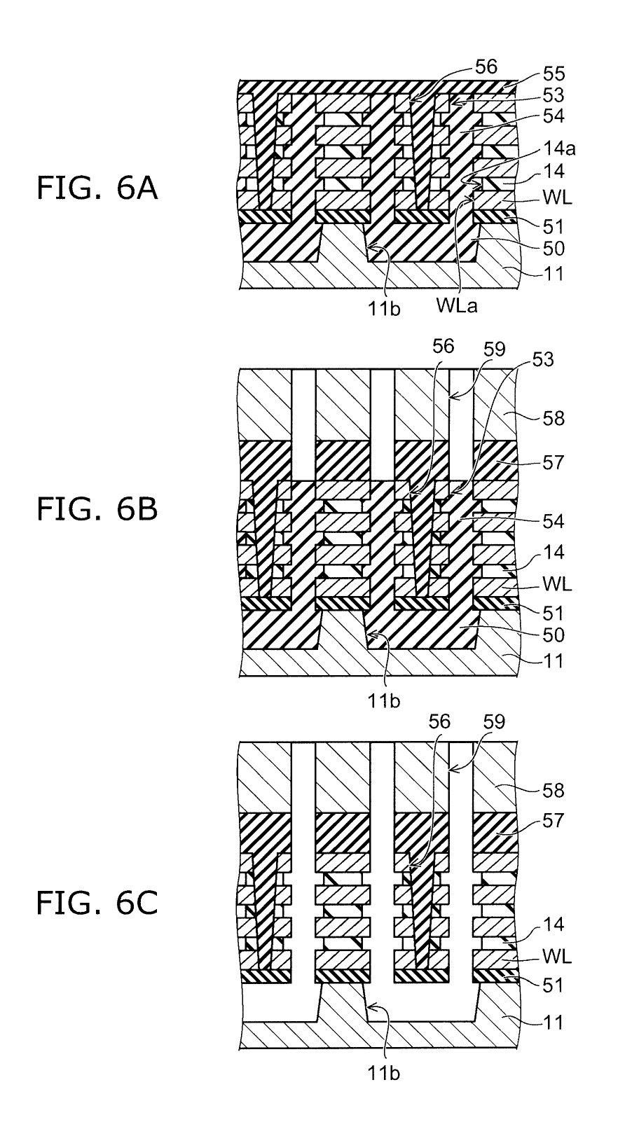

Next, as shown in FIG. 6A, the space formed by removing the sacrificial film 52 is filled with e.g. silicon oxide. Thus, the space between the electrode films WL is filled with e.g. silicon oxide to form an interelectrode insulating film 14. Here, part of the side surface of the sacrificial member 54 is inserted between the electrode films WL. Hence, the end portion 14a of the interelectrode insulating film 14 is provided at a position farther from the sacrificial member 54 than the end portion WLa of the electrode film WL.

Next, as shown in FIG. 6B, an insulating film 57 made of e.g. silicon oxide is formed to a thickness capable of sufficiently ensuring insulation between the uppermost electrode film WL and the select gate electrode SG. Then, a gate electrode film 58 constituting a select gate electrode SG is formed on the insulating film 57. The gate electrode film 58 can be formed from e.g. boron-doped polysilicon. The gate electrode film 58 is formed to a thickness such that the gate electrode film 58 can function as a select gate electrode SG. Etching is performed from above the formed gate electrode film 58 to form a through hole 59 reaching the upper surface of the sacrificial member 54.

Next, as shown in FIG. 6C, the sacrificial member 50 and the sacrificial member 54 are removed by e.g. a hot phosphoric acid process. The removal of the sacrificial member 50 and the sacrificial member 54 can be performed through the through hole 59.

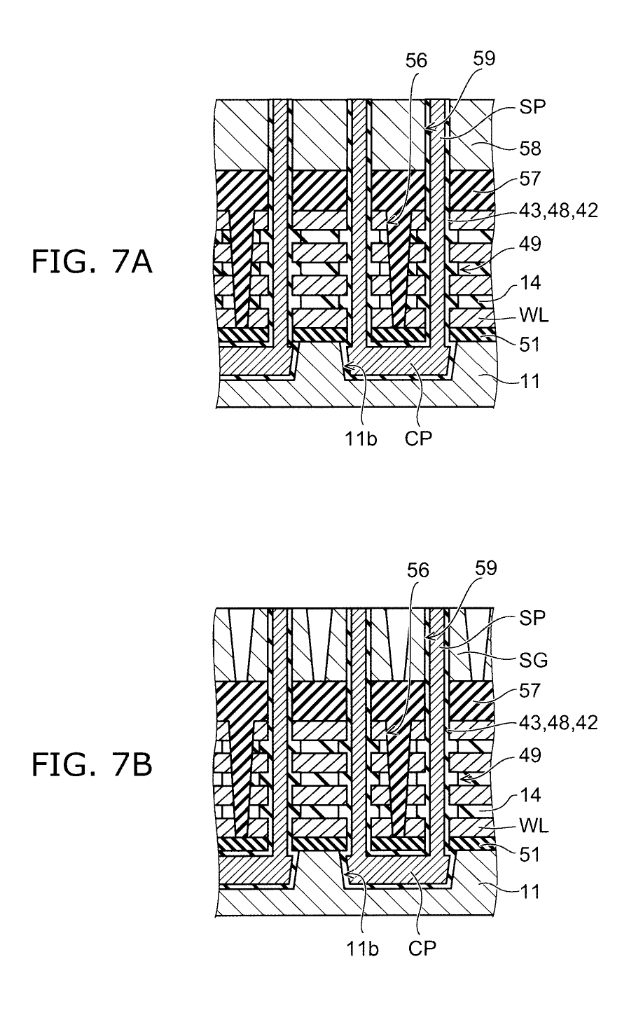

Next, as shown in FIG. 7A, an outer insulating film 43, a memory layer 48, and an inner insulating film 42 are formed in this order. Then, e.g. polysilicon is buried inside the inner insulating film 42 to form a semiconductor pillar SP and a connecting portion CP. Subsequently, by overall etching, etch back is performed until the gate electrode film 58 is exposed.

Here, part of the side surface of the sacrificial member 54 has been inserted between the electrode films WL. Hence, a protrusion 49 is provided as a projection of at least the outer insulating film 43 projected radially outside the semiconductor pillar SP.

Here, the protrusion 49 can also be a projection in which the outer insulating film 43, the memory layer 48, and the inner insulating film 42 are projected. Alternatively, the protrusion 49 can also be a projection in which the outer insulating film 43 and the memory layer 48 are projected, or a projection in which the outer insulating film 43 is projected.

Next, as shown in FIG. 7B, the gate electrode film 58 is divided by dry etching or wet etching to form a select gate electrode SG.

Subsequently, contacts and wirings are formed as appropriate. Thus, a nonvolatile semiconductor memory device is manufactured.

According to this embodiment, the portion 52a of the sacrificial film 52 facing the through hole 53 is removed by a prescribed dimension. Hence, part of the side surface of the sacrificial member 54 can be inserted between the electrode films WL.

Thus, the electrode film WL can be supported in the manner of sandwiching the electrode film WL by the portion inserted between the electrode films WL. This can suppress the variation in the position of the electrode film WL due to stress by chemicals and surface tension of chemicals. Consequently, contact between the electrode films WL can be suppressed, and hence the yield can be increased.

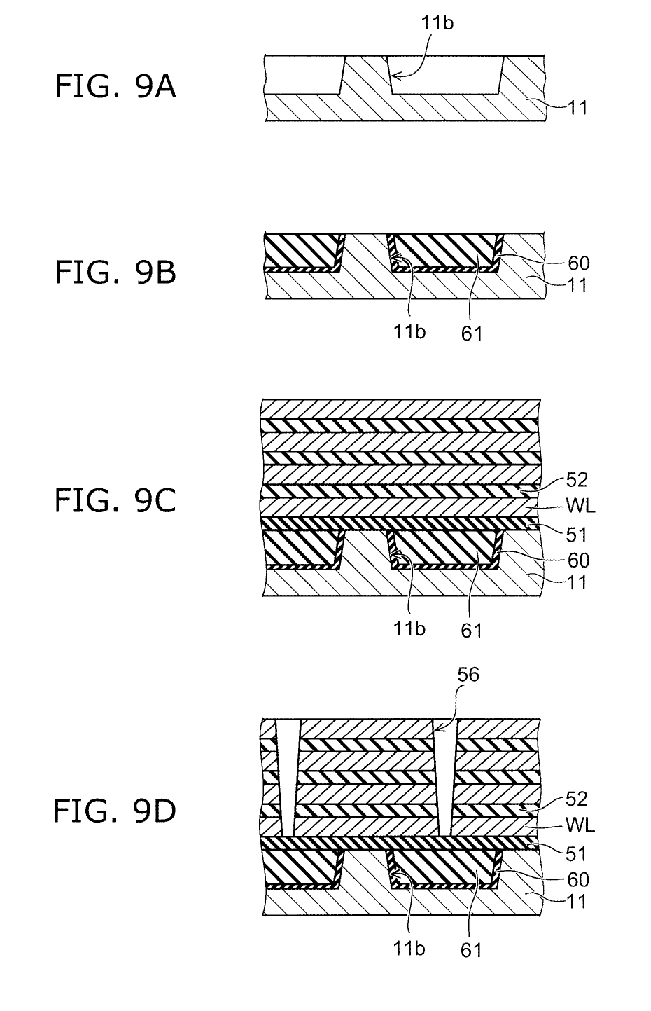

Furthermore, more interelectrode insulating films 14 can be provided than in the example illustrated in FIGS. 9A to 12B. Hence, the resistance can be reduced, and the operating characteristics of the nonvolatile semiconductor memory device can be improved.

### Fourth Embodiment

FIGS. 9A to 12B are schematic process sectional views illustrating a method for manufacturing a nonvolatile semiconductor memory device according to a fourth embodiment.

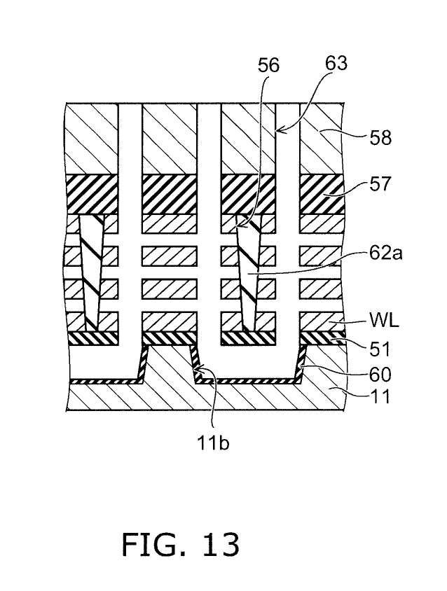

FIG. 13 is a schematic process sectional view illustrating a method for manufacturing a nonvolatile semiconductor memory device according to a comparative example.

First, transistors (transistors in a peripheral circuit unit), not shown, for controlling memory cells MC are formed in a semiconductor substrate 11.

Then, a polysilicon film is formed so as to cover the transistors. Then, as shown in FIG. 9A, a trench 11b is formed in the surface of the formed polysilicon film by photolithography.

Next, as shown in FIG. 9B, an insulating film 60 (fourth insulating film) is formed. Then, a sacrificial member 61 illustratively made of non-doped polysilicon is buried so as to cover the insulating film 60. Then, by overall etching, etch back is performed until the semiconductor substrate 11 is exposed.

Next, as shown in FIG. 9C, an insulating film 51 made of e.g. silicon oxide is formed to a thickness capable of maintaining insulation between the semiconductor substrate 11 and the lowermost electrode film WL. Then, electrode films WL and sacrificial films 52 are alternately stacked on the insulating film 51 to form a multilayer body. That is, a multilayer body is formed above the semiconductor substrate 11 with the sacrificial member 61 buried therein.

Here, the electrode film WL is formed from e.g. boron-doped polysilicon to a thickness such that the electrode film WL can function as a gate electrode.

The sacrificial film 52 can be formed from e.g. non-doped polysilicon.

While the case of stacking four electrode films WL is illustrated as an example, the number of stacked layers can be modified as appropriate.

Next, as shown in FIG. 9D, etching is performed from above the multilayer body to form a trench 56 penetrating through the multilayer body in the Z-axis direction to the insulating film 51.

The electrode films WL are divided by the trench 56 so that the lower end of the trench 56 is located above around the center of the sacrificial member 61.

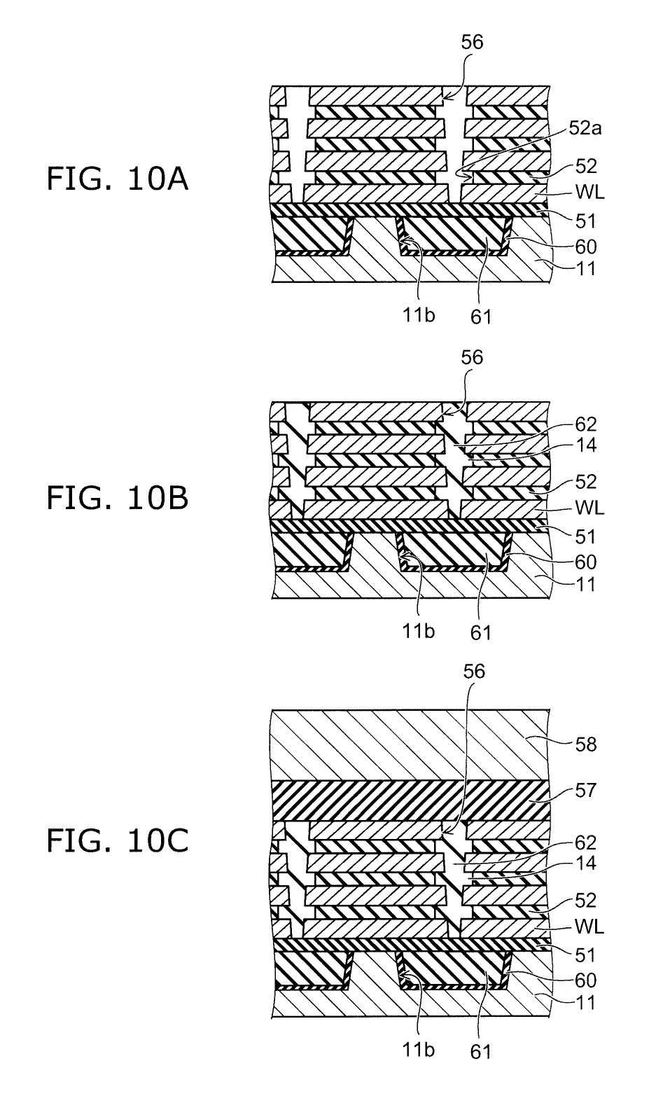

Next, as shown in FIG. 10A, the sacrificial film 52 is removed by a prescribed amount using dry etching or wet etching.

That is, the portion 52b of the sacrificial film 52 facing the trench 56 is removed by a prescribed dimension through the trench 56. For instance, the sacrificial film 52 can be removed by 10 nm or more from the inner surface of the trench 56. However, the removed amount is set so as not to reach the through hole 63 to be formed later.

Examples of the dry etching can include reactive ion etching (RIE). Examples of the wet etching can include a process using chemicals such as dilute hydrofluoric acid. However, the etching process is not limited thereto, but a process capable of selectively removing the sacrificial film 52 can be selected as appropriate.

Next, as shown in FIG. 10B, the trench 56 is filled with an insulating film 62 (third insulating film) made of e.g. silicon oxide. Then, by overall etching, etch back is performed until the uppermost electrode film WL is exposed.

At this time, the portion 52b of the sacrificial film 52 facing the trench 56 has been removed by a prescribed dimension. Hence, part of the side surface of the insulating film 62 is inserted between the electrode films WL. That is, in the step of filling the trench 56 with the insulating film 62, the space formed by removing the sacrificial film 52 is also filled with the insulating film 62. The portion inserted between the electrode films WL constitutes an interelectrode insulating film 14.

Next, as shown in FIG. 10C, an insulating film 57 made of e.g. silicon oxide is formed to a thickness capable of sufficiently ensuring insulation between the uppermost electrode film WL and the select gate electrode SG. Then, a gate electrode film 58 constituting a select gate electrode SG is formed on the insulating film 57. The gate electrode film 58 can be formed from e.g. boron-doped polysilicon. The gate electrode film 58 is formed to a thickness such that the gate electrode film 58 can function as a select gate electrode SG.

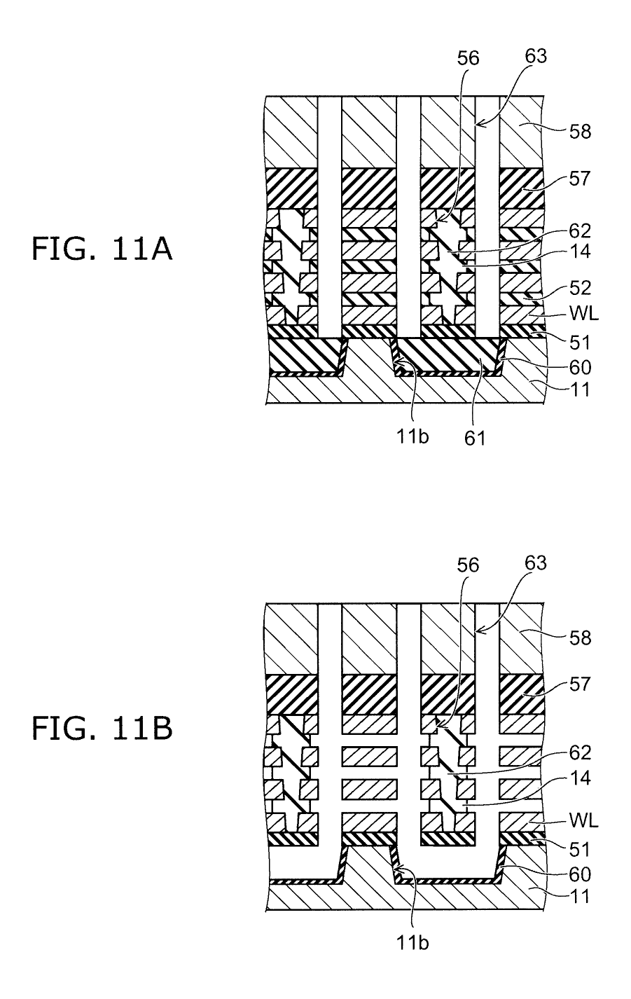

Next, as shown in FIG. 11A, etching is performed from above the multilayer body to form through holes 63 reaching both end portions of the sacrificial member 61.

Next, as shown in FIG. 11B, the sacrificial film 52 and the sacrificial member 61 are removed by e.g. wet etching. The removal of the sacrificial film 52 and the sacrificial member 61 can be performed through the through hole 63. Examples of the wet etching can include an alkaline chemical treatment.

Here, when the sacrificial film 52 and the sacrificial member 61 are removed, the position of the electrode film WL may vary due to stress by chemicals and surface tension of chemicals.

For instance, in the case where an insulating film 62a having a planar side surface is formed as in the comparable example shown in FIG. 13, when the sacrificial film 52 and the sacrificial member 61 are removed, the portion supporting the electrode film WL is only the side surface of the insulating film 62a. Hence, the force supporting the electrode film WL is weak. Thus, the position of the electrode film WL may vary due to stress by chemicals and surface tension of chemicals. Then, by the variation in the position of the electrode film WL, the electrode films WL may be brought into contact with each other. This may decrease the yield.

In contrast, according to this embodiment, as illustrated in FIG. 10A, the portion 52b of the sacrificial film 52 facing the trench 56 is removed by a prescribed dimension. Hence, part of the side surface of the insulating film 62 can be inserted between the electrode films WL.

Thus, the electrode film WL can be supported in the manner of sandwiching the electrode film WL by the portion inserted between the electrode films WL. This can suppress the variation in the position of the electrode film WL due to stress by chemicals and surface tension of chemicals. Consequently, contact between the electrode films WL can be suppressed, and hence the yield can be increased.

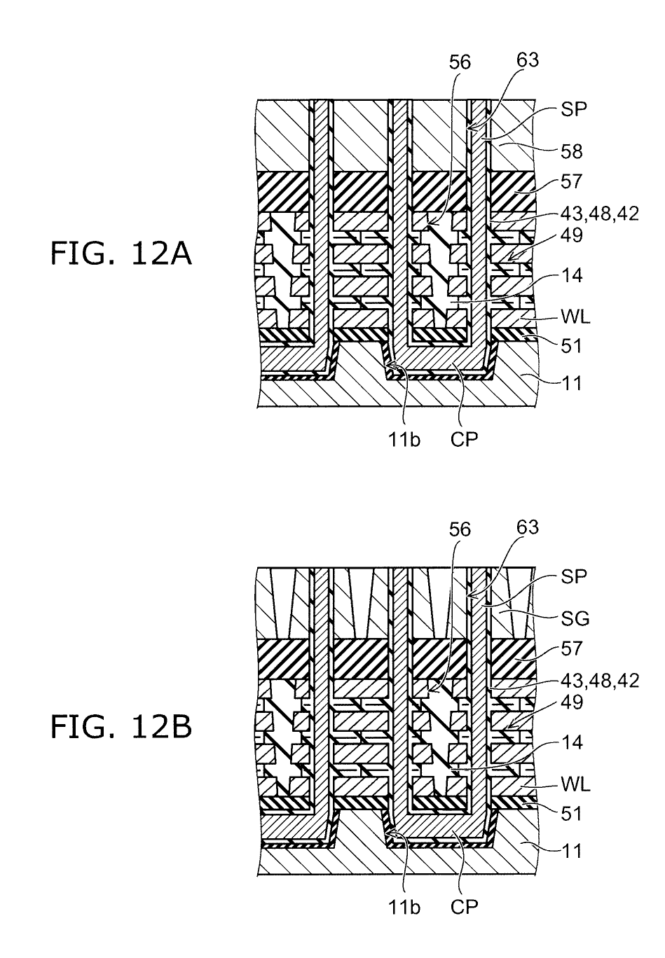

Next, as shown in FIG. 12A, an outer insulating film 43, a memory layer 48, and an inner insulating film 42 are formed in this order. Then, e.g. polysilicon is buried inside the inner insulating film 42 to form a semiconductor pillar SP and a connecting portion CP. Subsequently, by overall etching, etch back is performed until the gate electrode film 58 is exposed.

Here, the outer insulating film 43 and the like are formed in the space formed by removing the sacrificial film 52. Hence, a protrusion 49 is provided as a projection of at least the outer insulating film 43 projected radially outside the semiconductor pillar SP.

Here, the protrusion 49 can also be a projection in which the outer insulating film 43, the memory layer 48, and the inner insulating film 42 are projected. Alternatively, the protrusion 49 can also be a projection in which the outer insulating film 43 and the memory layer 48 are projected, or a projection in which the outer insulating film 43 is projected.

Next, as shown in FIG. 12B, the gate electrode film 58 is divided by dry etching or wet etching to form a select gate electrode SG.

Subsequently, contacts and wirings are formed as appropriate. Thus, a nonvolatile semiconductor memory device is manufactured.

According to this embodiment, the portion 52b of the sacrificial film 52 facing the trench 56 is removed by a prescribed dimension. Hence, part of the side surface of the insulating film 62 can be inserted between the electrode films WL.

Thus, the electrode film WL can be supported in the manner of sandwiching the electrode film WL by the portion inserted between the electrode films WL. This can suppress the variation in the position of the electrode film WL due to stress by chemicals and surface tension of chemicals. Consequently, contact between the electrode films WL can be suppressed, and hence the yield can be increased.

Furthermore, the number of process steps can be made smaller than in the example illustrated in FIGS. 4A to 7B. Furthermore, modifications to the existing manufacturing process can be reduced. Hence, the productivity can be improved.

### Fifth Embodiment

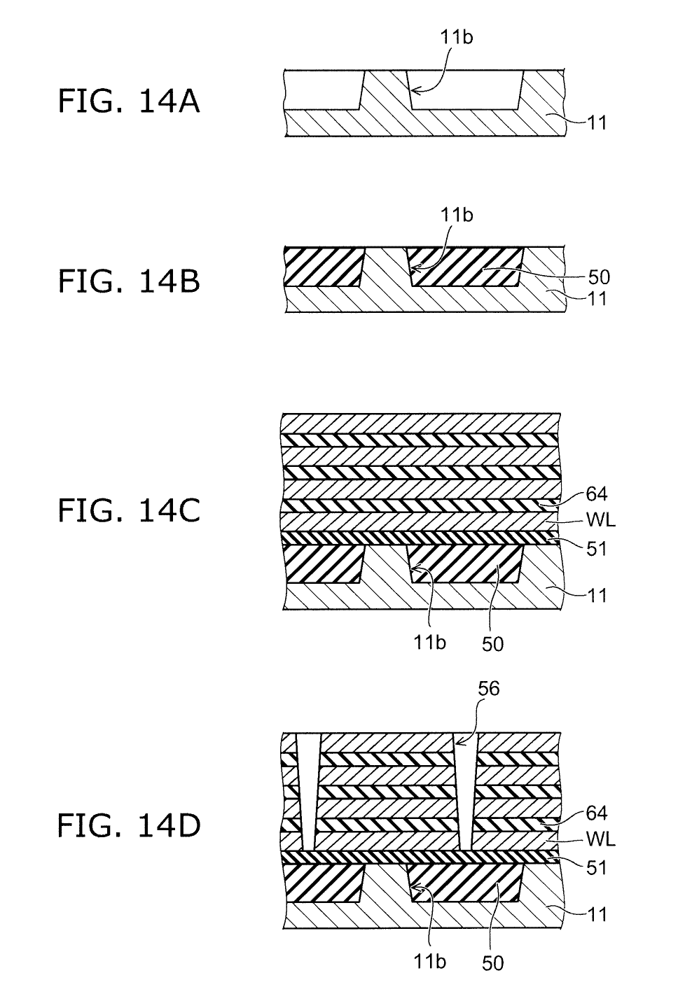

FIGS. 14A to 17B are schematic process sectional views illustrating a method for manufacturing a nonvolatile semiconductor memory device according to a fifth embodiment.

First, transistors (transistors in a peripheral circuit unit), not shown, for controlling memory cells MC are formed in a semiconductor substrate 11.

Then, a polysilicon film is formed so as to cover the transistors. Then, as shown in FIG. 14A, a trench 11b is formed in the surface of the formed polysilicon film by photolithography.

Next, as shown in FIG. 14B, a sacrificial member 50 illustratively made of silicon nitride is buried in the trench 11b. Then, by overall etching, etch back is performed until the semiconductor substrate 11 is exposed.

Next, as shown in FIG. 14C, an insulating film 51 made of e.g. silicon oxide is formed to a thickness capable of maintaining insulation between the semiconductor substrate 11 and the lowermost electrode film WL. Then, electrode films WL and sacrificial films 64 are alternately stacked on the insulating film 51 to form a multilayer body. That is, a multilayer body is formed above the semiconductor substrate 11 with the sacrificial member 50 buried therein.

Here, the electrode film WL is formed from e.g. boron-doped polysilicon to a thickness such that the electrode film WL can function as a gate electrode.

The sacrificial film 64 can be formed from e.g. silicon nitride. While the case of stacking four electrode films WL is illustrated as an example, the number of stacked layers can be modified as appropriate.

Next, as shown in FIG. 14D, etching is performed from above the multilayer body to form a trench 56 penetrating through the multilayer body in the Z-axis direction to the insulating film 51.

The electrode films WL are divided by the trench 56 so that the lower end of the trench 56 is located above around the center of the sacrificial member 50.

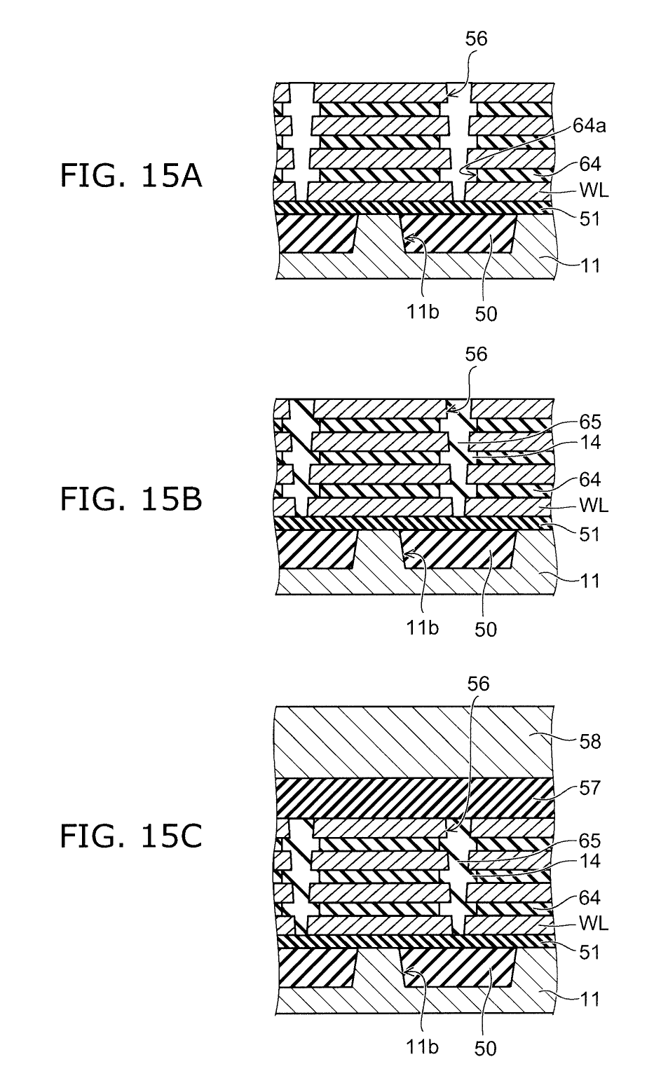

Next, as shown in FIG. 15A, the sacrificial film 64 is removed by a prescribed amount using dry etching or wet etching.

That is, the portion 64a of the sacrificial film 64 facing the trench 56 is removed by a prescribed dimension through the trench 56. For instance, the sacrificial film 64 can be removed by 10 nm or more from the inner surface of the trench 56. However, the removed amount is set so as not to reach the through hole 63 to be formed later.

Examples of the dry etching can include reactive ion etching (RIE). Examples of the wet etching can include a process using chemicals such as dilute hydrofluoric acid. However, the etching process is not limited thereto, but a process capable of selectively removing the sacrificial film 64 can be selected as appropriate.

Next, as shown in FIG. 15B, the trench 56 is filled with an insulating film 65 (third insulating film) made of e.g. silicon oxide. Then, by overall etching, etch back is performed until the uppermost electrode film WL is exposed.

At this time, the portion 64a of the sacrificial film 64 facing the trench 56 has been removed by a prescribed dimension. Hence, part of the side surface of the insulating film 65 is inserted between the electrode films WL. That is, in the step of filling the trench 56 with the insulating film 65, the space formed by removing the sacrificial film 64 is also filled with the insulating film 65. The portion inserted between the electrode films WL constitutes an interelectrode insulating film 14.

Next, as shown in FIG. 15C, an insulating film 57 made of e.g. silicon oxide is formed to a thickness capable of sufficiently ensuring insulation between the uppermost electrode film WL and the select gate electrode SG. Then, a gate electrode film 58 constituting a select gate electrode SG is formed on the insulating film 57. The gate electrode film 58 can be formed from e.g. boron-doped polysilicon. The gate electrode film 58 is formed to a thickness such that the gate electrode film 58 can function as a select gate electrode SG.

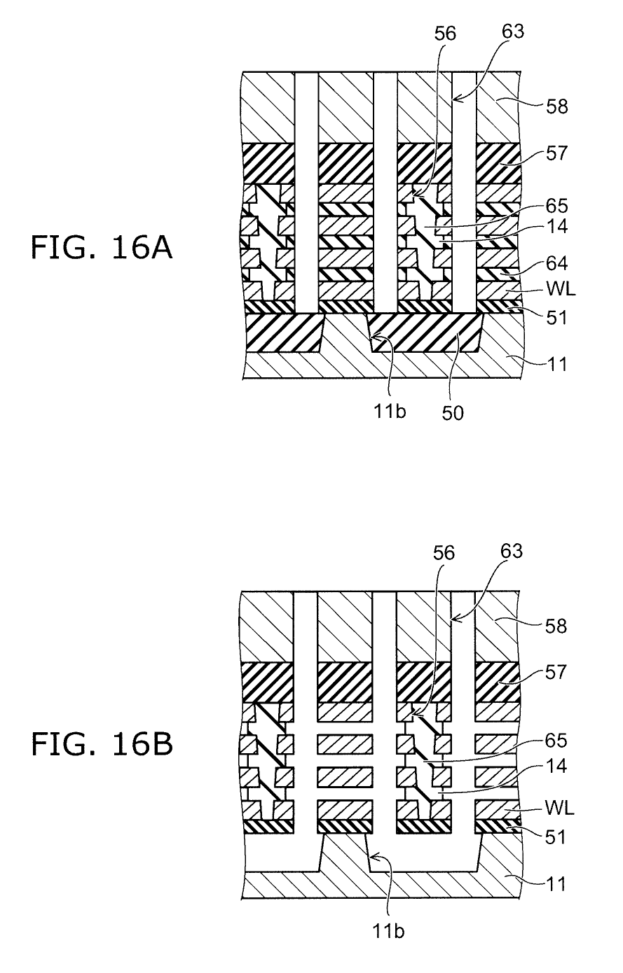

Next, as shown in FIG. 16A, etching is performed from above the multilayer body to form through holes 63 reaching both end portions of the sacrificial member 50.

Next, as shown in FIG. 16B, the sacrificial film 64 and the sacrificial member 50 are removed by e.g. a hot phosphoric acid process. The removal of the sacrificial film 64 and the sacrificial member 50 can be performed through the through hole 63.

Here, when the sacrificial film 64 and the sacrificial member 50 are removed, the position of the electrode film WL may vary due to stress by chemicals and surface tension of chemicals.

For instance, in the case where an insulating film 62a having a planar side surface is formed as in the comparable example shown in FIG. 13, when the sacrificial film 64 and the sacrificial member 50 are removed, the portion supporting the electrode film WL is only the side surface of the insulating film 62a. Hence, the force supporting the electrode film WL is weak. Thus, the position of the electrode film WL may vary due to stress by chemicals and surface tension of chemicals. Then, by the variation in the position of the electrode film WL, the electrode films WL may be brought into contact with each other. This may decrease the yield.

In contrast, according to this embodiment, as illustrated in FIG. 15A, the portion 64a of the sacrificial film 64 facing the trench 56 is removed by a prescribed dimension. Hence, part of the side surface of the insulating film 65 can be inserted between the electrode films WL.

Thus, the electrode film WL can be supported in the manner of sandwiching the electrode film WL by the portion inserted between the electrode films WL. This can suppress the variation in the position of the electrode film WL due to stress by chemicals and surface tension of chemicals. Consequently, contact between the electrode films WL can be suppressed, and hence the yield can be increased.

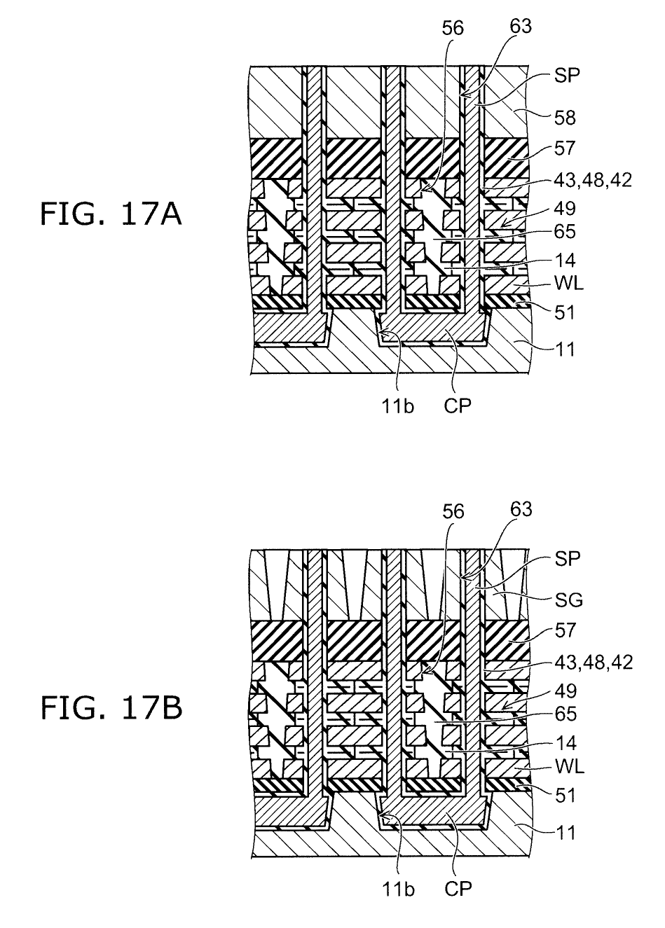

Next, as shown in FIG. 17A, an outer insulating film 43, a memory layer 48, and an inner insulating film 42 are formed in this order. Then, e.g. polysilicon is buried inside the inner insulating film 42 to form a semiconductor pillar SP and a connecting portion CP. Subsequently, by overall etching, etch back is performed until the gate electrode film 58 is exposed.

Here, the outer insulating film 43 and the like are formed in the space formed by removing the sacrificial film 64. Hence, a protrusion 49 is provided as a projection of at least the outer insulating film 43 projected radially outside the semiconductor pillar SP.

Here, the protrusion 49 can also be a projection in which the outer insulating film 43, the memory layer 48, and the inner insulating film 42 are projected. Alternatively, the protrusion 49 can also be a projection in which the outer insulating film 43 and the memory layer 48 are projected, or a projection in which the outer insulating film 43 is projected.

Next, as shown in FIG. 17B, the gate electrode film 58 is divided by dry etching or wet etching to form a select gate electrode SG.

Subsequently, contacts and wirings are formed as appropriate. Thus, a nonvolatile semiconductor memory device is manufactured.

According to this embodiment, the portion 64a of the sacrificial film 64 facing the trench 56 is removed by a prescribed dimension. Hence, part of the side surface of the insulating film 65 can be inserted between the electrode films WL.

Thus, the electrode film WL can be supported in the manner of sandwiching the electrode film WL by the portion inserted between the electrode films WL. This can suppress the variation in the position of the electrode film WL due to stress by chemicals and surface tension of chemicals. Consequently, contact between the electrode films WL can be suppressed, and hence the yield can be increased.

Furthermore, the number of process steps can be made smaller than in the example illustrated in FIGS. 4A to 7B. Furthermore, modifications to the existing manufacturing process can be reduced. Hence, the productivity can be improved.

The examples illustrated above are methods for manufacturing a nonvolatile semiconductor memory device including U-shaped semiconductor pillars as illustrated in e.g. FIG. 1.

These examples are also applicable to a method for manufacturing a nonvolatile semiconductor memory device including independent semiconductor pillars SP as illustrated in e.g. FIG. 3.

For instance, also in the method for manufacturing a nonvolatile semiconductor memory device including independent semiconductor pillars SP as illustrated in FIG. 3, part of the side surface of the sacrificial member 54 can be inserted between the electrode films WL, part of the side surface of the insulating film 62 can be inserted between the electrode films WL, and part of the side surface of the insulating film 65 can be inserted between the electrode films WL. This can suppress the variation in the position of the electrode film WL due to stress by chemicals and surface tension of chemicals. Consequently, contact between the electrode films WL can be suppressed, and hence the yield can be increased.

Here, formation itself of each component of the nonvolatile semiconductor memory device as illustrated in FIG. 3 can be made similar to those described above, and hence the detailed description thereof is omitted.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

For instance, the shape, dimension, material, layout, and number of the components in the nonvolatile semiconductor memory device 110 and nonvolatile semiconductor memory device 120 are not limited to those illustrated above, but can be modified as appropriate.

1. A nonvolatile semiconductor memory device comprising:
a multilayer body including a plurality of interelectrode insulating films and a plurality of electrode films alternately stacked in a first direction;
a semiconductor pillar penetrating through the multilayer body in the first direction;
a memory layer provided between each of the electrode films and the semiconductor pillar and extending in the first direction;
a first insulating film provided between the memory layer and the semiconductor pillar and extending in the first direction; and
a second insulating film provided between each of the electrode films and the memory layer and extending in the first direction,
the second insulating film being projected between the electrode films.

2. The device according to claim 1, wherein the memory layer is projected between the electrode films.

3. The device according to claim 2, wherein the first insulating film is projected between the electrode films.

4. The device according to claim 1, wherein an end portion of one of the interelectrode insulating films facing the semiconductor pillar is provided at a position farther from the semiconductor pillar than an end portion of one of the electrode films facing the semiconductor pillar.

5. The device according to claim 1, wherein the second insulating film retains a position of one of the electrode films in the first direction by being projected between the electrode films.

6. The device according to claim 1, further comprising:
a connecting portion provided below the multilayer body and connecting lower end portions of a pair of the adjacent semiconductor pillars to each other;
a plurality of bit lines provided above the multilayer body and extending in a second direction orthogonal to the first direction; and
a plurality of source lines provided above the multilayer body and extending in another direction being orthogonal to the first direction and crossing the second direction,
one of the pair of the semiconductor pillars being connected to the source line, and another one of the pair being connected to the bit line.

7. The device according to claim 1, further comprising:
a plurality of bit lines provided above the multilayer body and extending in a second direction orthogonal to the first direction; and
a plurality of source lines provided below the multilayer body and extending in the second direction,
one end of the semiconductor pillar being connected to the source line, and another end of the semiconductor pillar being connected to the bit line.

8. The device according to claim 1, wherein the second insulating film is a single layer film made of a material selected from the group consisting of silicon oxide, silicon nitride, silicon oxynitride, aluminum oxide, aluminum oxynitride, hafnia, hafnium aluminate, hafnia nitride, hafnium nitride aluminate, hafnium silicate, hafnium nitride silicate, lanthanum oxide, and lanthanum aluminate, or a multilayer film made of a plurality of materials selected from the group.

9. The device according to claim 1, wherein the memory layer is a single layer film made of a material selected from the group consisting of silicon nitride, silicon oxynitride, aluminum oxide, aluminum oxynitride, hafnia, hafnium aluminate, hafnia nitride, hafnium nitride aluminate, hafnium silicate, hafnium nitride silicate, lanthanum oxide, and lanthanum aluminate, or a multilayer film made of a plurality of materials selected from the group.

10. The device according to claim 1, wherein the first insulating film is a single layer film made of a material selected from the group consisting of silicon oxide, silicon nitride, silicon oxynitride, aluminum oxide, aluminum oxynitride, hafnia, hafnium aluminate, hafnia nitride, hafnium nitride aluminate, hafnium silicate, hafnium nitride silicate, lanthanum oxide, and lanthanum aluminate, or a multilayer film made of a plurality of materials selected from the group.

11. A method for manufacturing a nonvolatile semiconductor memory device, comprising:
forming a multilayer body by alternately stacking a plurality of sacrificial films and a plurality of electrode films in a first direction;
forming a through hole penetrating through the multilayer body in the first direction;
removing a portion of the sacrificial films facing the through hole by a prescribed dimension;
filling the through hole with a first sacrificial member;
forming a first trench penetrating through the multilayer body in the first direction;
removing the sacrificial films through the first trench;
forming an interelectrode insulating film through the first trench;
removing the first sacrificial member; and
forming a second insulating film, a memory layer, and a first insulating film in this order on an inner surface of the through hole, and burying silicon inside the first insulating film.

12. The method according to claim 11, wherein in the filling the through hole with a first sacrificial member, a space formed by removing the sacrificial films is also filled with the first sacrificial member.

13. The method according to claim 11, further comprising:
forming a second trench in a surface of a substrate; and
burying a second sacrificial member in the second trench,
the multilayer body being formed above the substrate with the second sacrificial member buried in the substrate,
the through hole reaching both end portions of the second sacrificial member being formed, and
the first trench being formed so that a lower end of the first trench is located above around center of the second sacrificial member.

14. The method according to claim 11, wherein the sacrificial films are removed by an alkaline chemical treatment through the first trench.

15. The method according to claim 11, wherein the first sacrificial member is removed by a hot phosphoric acid process.

16. A method for manufacturing a nonvolatile semiconductor memory device, comprising:
forming a multilayer body by alternately stacking a plurality of sacrificial films and a plurality of electrode films in a first direction;
forming a first trench penetrating through the multilayer body in the first direction;
removing a portion of the sacrificial films facing the first trench by a prescribed dimension;
filling the first trench with a third insulating film;
forming a through hole penetrating through the multilayer body in the first direction;
removing the sacrificial films through the through hole; and
forming a second insulating film, a memory layer, and a first insulating film in this order on an inner surface of the through hole, and burying silicon inside the first insulating film.

17. The method according to claim 16, wherein in the filling the first trench with a third insulating film, a space formed by removing the sacrificial films is also filled with the third insulating film.

18. The method according to claim 16, further comprising:
forming a second trench in a surface of a substrate; and
burying a second sacrificial member in the second trench,
the multilayer body being formed above the substrate with the second sacrificial member buried in the substrate,
the first trench being formed so that a lower end of the first trench is located above around center of the second sacrificial member, and
the through hole reaching both end portions of the second sacrificial member being formed.

19. The method according to claim 18, further comprising:
forming a fourth insulating film in the second trench,
the second sacrificial member being buried so as to cover the fourth insulating film.

20. The method according to claim 16, wherein the sacrificial films are removed by an alkaline chemical treatment or a hot phosphoric acid process through the through hole.
